(19) United States
(12) Patent Application Publication
(10) Pub. No.: US 2023/0064180 A1
(43) Pub. Date: Mar. 2, 2023

(54) SEMICONDUCTOR DEVICE AND SEMICONDUCTOR MEMORY DEVICE

(71) Applicant: Kioxia Corporation, Tokyo (JP)

(72) Inventor: Kazunari TOYONAGA, Yokkaichi Mie (JP)

(73) Assignee: Kioxia Corporation, Tokyo (JP)

(21) Appl. No.: 17/701,024

(22) Filed: Mar. 22, 2022

(30) Foreign Application Priority Data
Sep. 1, 2021 (JP) 2021-142804

(51) Int. Cl. H01L 27/11556; G11C 16/04; H01L 27/11519; H01L 27/11524; H01L 27/11565; H01L 27/1157; H01L 27/11582

(52) U.S. Cl. CPC H01L 27/11556; G11C 16/0483; H01L 27/11519; H01L 27/11524; H01L 27/11565; H01L 27/1157; H01L 27/11582

(57) ABSTRACT

A semiconductor device includes: a semiconductor substrate, an element isolation insulating layer disposed on the semiconductor substrate, and a plurality of conductive layers opposed to the semiconductor substrate and the element isolation insulating layer. The semiconductor substrate includes a first active region and a second active region arranged in a first direction along a main surface. The first element isolation insulating layer is disposed between the first active region and the second active region. The plurality of conductive layers include a first electrode and a second electrode opposed to the element isolation insulating layer in a second direction intersecting with the main surface of the semiconductor substrate, and arranged in the first direction, the first electrode being disposed on the first active region side and the second electrode disposed on the second active region side.

### CROSS-REFERENCE TO RELATED APPLICATIONS

This application is based upon and claims the benefit of Japanese Patent Application No. 2021-142804, filed on Sep. 1, 2021, the entire contents of which are incorporated herein by reference.

### BACKGROUND

### Field

Embodiments described herein relate generally to a semiconductor device and a semiconductor memory device.

### Description of the Related Art

There has been known a semiconductor device and a semiconductor memory device that include a semiconductor substrate and a plurality of transistors formed on the semiconductor substrate.

### BRIEF DESCRIPTION OF THE DRAWINGS

FIG. 1 is a schematic equivalent circuit diagram of a semiconductor memory device according to a first embodiment;

FIG. 2 is a schematic perspective view of the semiconductor memory device;

FIG. 3 is a schematic enlarged view of FIG. 2;

FIG. 4 is a schematic plan view of the semiconductor memory device;

FIG. 5 is a schematic enlarged view of FIG. 4;

FIG. 6 is a schematic enlarged view of FIG. 5;

FIG. 7 is a schematic enlarged view of FIG. 5;

FIG. 8 is a schematic cross-sectional view of a structure illustrated in FIG. 7 cut along the line A-A′ and viewed in the arrow direction;

FIG. 9 is a schematic cross-sectional view of the structure illustrated in FIG. 7 cut along the line B-B′ and viewed in the arrow direction;

FIG. 10 is a schematic plan view of the semiconductor memory device;

FIG. 11 is an enlarged schematic plan view of a part of FIG. 10;

FIG. 12 is a schematic cross-sectional view of the structure illustrated in FIG. 11 cut along the line C-C′ and viewed in the arrow direction;

FIG. 13 is a schematic cross-sectional view of the structure illustrated in FIG. 11 cut along the line D-D and viewed in the arrow direction;

FIG. 14 is a schematic plan view illustrating a voltage applied state for the structure illustrated in FIG. 11;

FIG. 15 is an enlarged schematic plan view of a part of a semiconductor memory device according to a comparative example;

FIG. 16 is an enlarged schematic plan view of a part of a semiconductor memory device according to a second embodiment;

FIG. 17 is an enlarged schematic plan view of a part of a semiconductor memory device according to a third embodiment;

FIG. 18 is an enlarged schematic plan view of a part of a semiconductor memory device according to a fourth embodiment; and

FIG. 19 is an enlarged schematic plan view of a part of a semiconductor memory device according to a fifth embodiment.

### DETAILED DESCRIPTION

A semiconductor device and a semiconductor memory device that are preferably operable are provided.

A semiconductor device according to one embodiment comprises: a semiconductor substrate; an element isolation insulating layer provided on the semiconductor substrate; and a plurality of conductive layers facing to the semiconductor substrate and the element isolation insulating layer.

The semiconductor substrate includes a first active region and a second active region arranged in a first direction along a main surface of the semiconductor substrate, and the element isolation insulating layer is disposed between the first active region and the second active region.

The semiconductor device includes a first gate insulating film and a second gate insulating film respectively facing to the first active region and the second active region in a second direction intersecting with the main surface of the semiconductor substrate. The plurality of conductive layers include a first gate electrode and a second gate electrode respectively facing to the first gate insulating film and the second gate insulating film in the second direction. The plurality of conductive layers also include a first electrode and a second electrode facing to the element isolation insulating layer in the second direction and arranged in the first direction. The first electrode is disposed on the first active region side, and the second electrode is disposed on the second active region side.

A semiconductor memory device according to another embodiment comprises: a semiconductor substrate; an element isolation insulating layer disposed on the semiconductor substrate; a plurality of conductive layers facing to the semiconductor substrate and the element isolation insulating layer; and a memory cell array electrically connected to the semiconductor substrate.

The semiconductor substrate includes a first active region and a second active region arranged in a first direction along a main surface of the semiconductor substrate. The element isolation insulating layer is disposed between the first active region and the second active region.

The semiconductor memory device includes a first gate insulating film and a second gate insulating film respectively facing to the first active region and the second active region in a second direction intersecting with the main surface of the semiconductor substrate. The plurality of conductive layers include a first gate electrode and a second gate electrode respectively facing to the first gate insulating film and the second gate insulating film in the second direction, and a first electrode and a second electrode facing to the element isolation insulating layer in the second direction and arranged in the first direction. The first electrode is disposed on the first active region side, and the second electrode is disposed on the second active region side.

The memory cell array is electrically connected to the first active region and the second active region of the semiconductor substrate.

Next, the semiconductor device and the semiconductor memory device according to the embodiments will be described in detail with reference to the drawings. The following embodiments are only examples, and not described for the purpose of limiting the present invention.

In this specification, a direction parallel to a main surface of the semiconductor substrate is referred to as an X-direction, a direction parallel to the main surface of the semiconductor substrate and perpendicular to the X-direction is referred to as a Y-direction, and a direction perpendicular to the main surface of the semiconductor substrate is referred to as a Z-direction.

In this specification, a direction along a predetermined plane is referred to as a first direction, a direction intersecting with this predetermined plane is referred to as a second direction, and a direction intersecting with the first direction along this predetermined plane is referred to as a third direction in some cases. These first direction, second direction, and third direction may correspond to any of the X-direction, the Z-direction, and the Y-direction and need not to correspond to these directions.

Expressions such as “above” and “below” in this specification are based on the semiconductor substrate. For example, a direction away from the semiconductor substrate along the Z-direction is referred to as above and a direction approaching the semiconductor substrate along the Z-direction is referred to as below. A lower surface and a lower end portion of a certain configuration mean a surface and an end portion on the semiconductor substrate side of this configuration. An upper surface and an upper end portion of a certain configuration mean a surface and an end portion on a side opposite to the semiconductor substrate of this configuration. A surface intersecting with the X-direction or the Y-direction is referred to as a side surface and the like.

In this specification, when it is referred that a first configuration “is electrically connected” to a second configuration, the first configuration may be directly connected to the second configuration, or the first configuration may be connected to the second configuration via a wiring, a semiconductor member, a transistor, or the like. For example, when three transistors are connected in series, even when the second transistor is in OFF state, the first transistor is “electrically connected” to the third transistor.

In this specification, when it is referred that the first configuration “is connected between” the second configuration and a third configuration, it may mean that the first configuration, the second configuration, and the third configuration are connected in series and the first configuration is disposed in a current path between the second configuration and the third configuration.

In this specification, when it is referred that a circuit or the like “electrically conducts” two wirings or the like, it may mean, for example, that this circuit or the like includes a transistor or the like, this transistor or the like is disposed in a current path between the two wirings, and this transistor or the like is turned ON.

### First Embodiment

[Overall Configuration]

Next, with reference to drawings, a configuration of a semiconductor memory device according to a first embodiment will be described. The following drawings are schematic, and for convenience of description, a part of configurations is sometimes omitted.

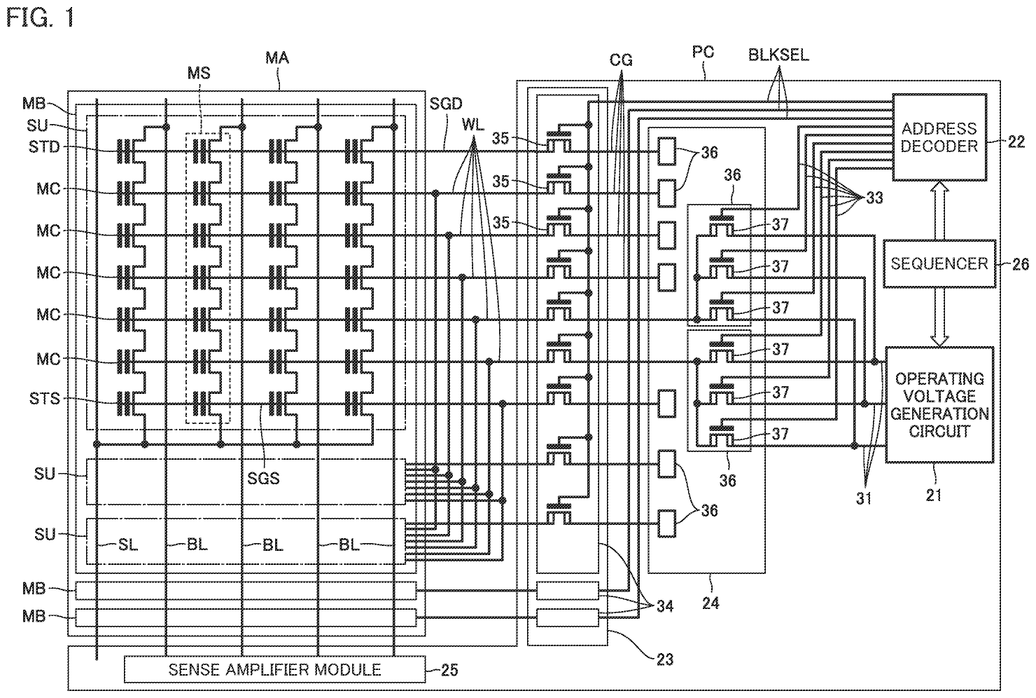

FIG. 1 is a schematic equivalent circuit diagram of a semiconductor memory device according to the first embodiment.

The semiconductor memory device according to the embodiment includes a memory cell array MA and a peripheral circuit PC controlling the memory cell array MA.

The memory cell array MA includes a plurality of memory blocks MB. These plurality of memory blocks MB each include a plurality of string units SU. These plurality of string units SU each include a plurality of memory strings MS. These plurality of memory strings MS have one ends each connected to the peripheral circuit PC via bit lines BL. These plurality of memory strings MS have other ends each connected to the peripheral circuit PC via a common source line SL.

The memory string MS includes a drain select transistor STD, a plurality of memory cells MC, and a source select transistor STS, which are connected in series between the bit line BL and the source line SL. Hereinafter, the drain select transistor STD and the source select transistor STS may be simply referred to as select transistors (STD, STS).

The memory cell MC according to the embodiment is a field-effect transistor that includes an electric charge storage film in a gate insulating film. The memory cell MC has a threshold voltage that varies according to an electric charge amount in the electric charge storage film. Word lines WL are connected to respective gate electrodes of the plurality of memory cells MC corresponding to one memory string MS. These respective word lines WL are connected to all of the memory strings MS in one memory block MB in common.

The select transistors (STD, STS) are field-effect transistors. Select gate lines (SGD, SGS) are connected to respective gate electrodes of the select transistors (STD, STS). The drain select line SGD is disposed corresponding to the string unit SU and connected to all of the memory strings MS in one string unit SU in common. The source select line SGS is connected to all of the memory strings MS in one memory block MB in common.

The peripheral circuit PC includes an operating voltage generation circuit 21 that generates operating voltages, an address decoder 22 that decodes address data, a block select circuit 23 and a voltage select circuit 24 that transfer the operating voltage to the memory cell array MA according to an output signal of the address decoder 22, a sense amplifier module 25 connected to the bit lines BL, and a sequencer 26 that controls them.

The operating voltage generation circuit 21 is connected to a plurality of operating voltage output terminals 31. The operating voltage generation circuit 21 includes, for example, a step down circuit, such as a regulator, and a step up circuit, such as a charge pump circuit. The operating voltage generation circuit 21, for example, generates a plurality of patterns of operating voltages applied to the bit line BL, the source line SL, the word line WL, and the select gate lines (SGD, SGS) in a read operation, a write operation, and an erase operation for the memory cell array MA, in response to a control signal from the sequencer 26 to output the operating voltages in parallel to the plurality of operating voltage output terminals 31. The operating voltages output from the operating voltage output terminals 31 are appropriately adjusted in accordance with the control signal from the sequencer 26.

The address decoder 22 is connected to a plurality of block select lines BLKSEL and a plurality of voltage select lines 33. For example, the address decoder 22 refers to address data of an address register in response to the control signal from the sequencer 26, decodes this address data to cause a block driving transistor 35 and a voltage select transistor 37 corresponding to the address data to be in a state of ON, and cause the block driving transistors 35 and the voltage select transistors 37 other than those to be in a state of OFF. For example, voltages of the block select line BLKSEL and the voltage select line 33 corresponding to the address data are set to be in a state of “H” and voltages of others are set to be in a state of “L.” When a P channel type transistor is used, instead of an N channel type transistor, as the block driving transistor 35 and the voltage select transistor 37, an inverse voltage is applied to these wirings.

In the illustrated example, in the address decoder 22, one block select line BLKSEL is connected to every memory block MB. However, this configuration is appropriately changeable. For example, one block select line BLKSEL may be provided for every two or more memory blocks MB.

The block select circuit 23 includes a plurality of block selectors 34 that correspond to the memory blocks MB. These plurality of block selectors 34 each include a plurality of the block driving transistors 35 corresponding to the word lines WL and the select gate lines (SGD, SGS). The block driving transistor 35 is, for example, a field-effect transistor that exhibits high breakdown voltage. The block driving transistors 35 have drain electrodes each electrically connected to the corresponding word line WL or the select gate line (SGD, SGS). The block driving transistors 35 have source electrodes each electrically connected to the operating voltage output terminal 31 via a wiring CG and the voltage select circuit 24. The block driving transistors 35 have gate electrodes commonly connected to the corresponding block select line BLKSEL.

Note that the block select circuit 23 further includes a plurality of transistors (not illustrated). These plurality of transistors are field-effect transistors that exhibits high breakdown voltage. These plurality of transistors connected between the select gate lines (SGD, SGS) and ground voltage supply terminals. These plurality of transistors electrically conduct the select gate lines (SGD, SGS) included in the unselected memory blocks MB with the ground voltage supply terminals. Note that the plurality of word lines WL included in the unselected memory blocks MB enter a floating state.

The voltage select circuit 24 includes a plurality of voltage selectors 36 corresponding to the word lines WL and the select gate lines (SGD, SGS). These plurality of voltage selectors 36 each include a plurality of the voltage select transistors 37. The voltage select transistor 37 is, for example, afield-effect transistor that exhibits high breakdown voltage. The voltage select transistors 37 have drain terminals that are each electrically connected to the corresponding word line WL or the select gate line (SGD, SGS) via the wiring CG and the block select circuit 23. The voltage select transistors 37 have source terminals each electrically connected to the corresponding operating voltage output terminal 31. The voltage select transistors 37 have gate electrodes each connected to the corresponding voltage select line 33.

The sense amplifier module 25 is connected to the plurality of bit lines BL. The sense amplifier module 25 includes, for example, a plurality of sense amplifier units corresponding to the bit lines BL. The sense amplifier units each include a clamp transistor that charges the bit line BL based on the voltage generated in the operating voltage generation circuit 21, a sense transistor that senses the voltage or a current of the bit line BL, a plurality of latch circuits that latch output signals, write data, and the like of this sense transistor.

The sequencer 26 outputs the control signal to the operating voltage generation circuit 21, the address decoder 22, and the sense amplifier module 25, according to an input instruction and a state of the semiconductor memory device. For example, the sequencer 26 sequentially refers to command data of a command register, decodes this command data, and outputs it to the operating voltage generation circuit 21, the address decoder 22, and the sense amplifier module 25.

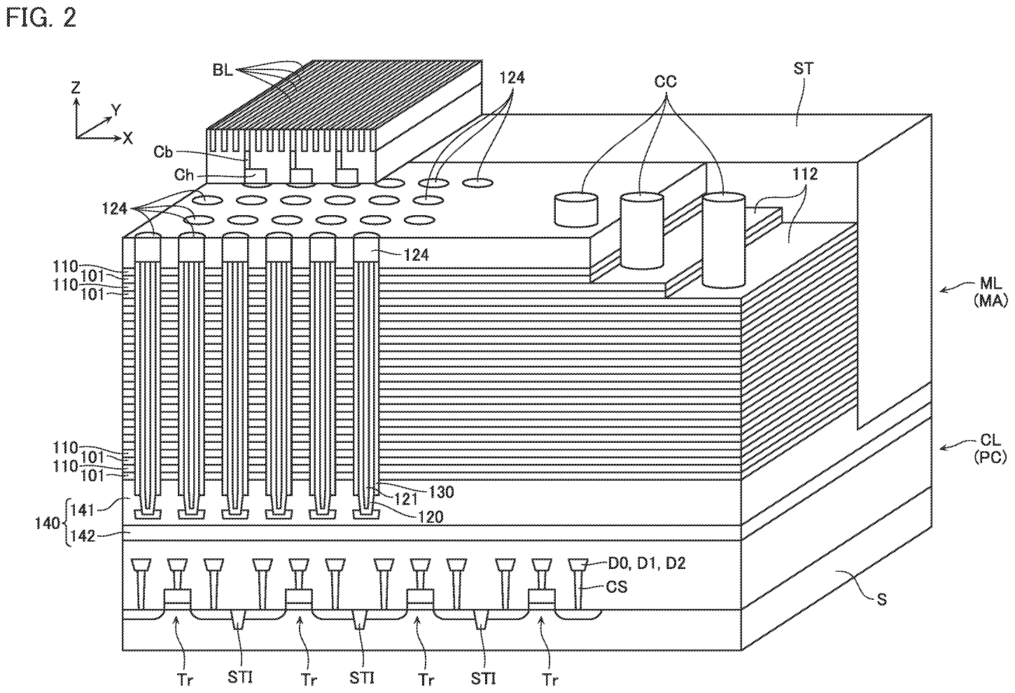

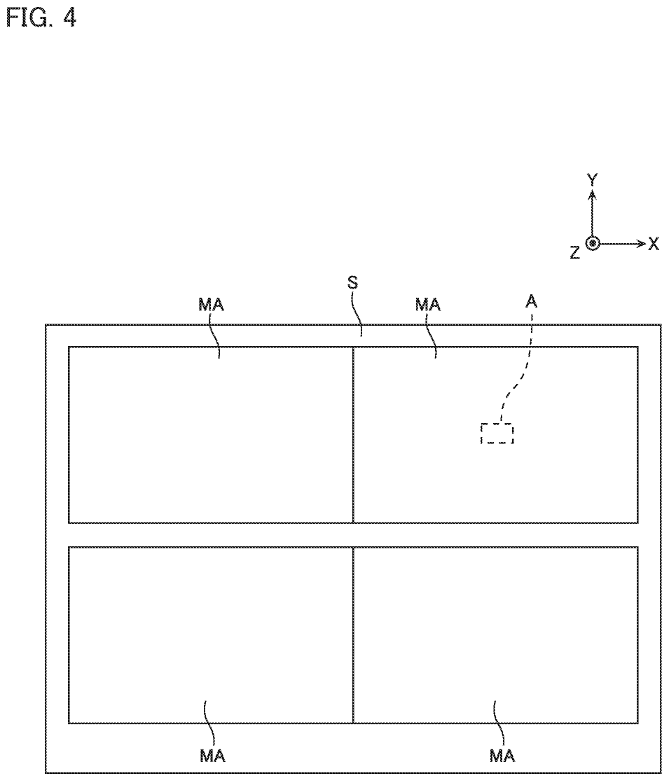

FIG. 2 is a schematic perspective view of the semiconductor memory device according to the embodiment. Note that FIG. 2 is a schematic structure for description and does not illustrate a detailed arrangement and the like of each configuration. More specific arrangement and the like of each configuration will be described later with reference to FIG. 4 to FIG. 11.

As illustrated in FIG. 2, the semiconductor memory device according to the embodiment includes a semiconductor substrate S, a circuit layer CL disposed on the semiconductor substrate S, and a memory layer ML disposed above the circuit layer CL.

The semiconductor substrate S includes, for example, single-crystal silicon (Si). The semiconductor substrate S has a double well structure that includes, for example, an N-type well on a surface of a P-type semiconductor substrate and further a P-type well in this N-type well. The semiconductor substrate S includes insulating layers STI including such as silicon oxide (SiO₂).

The circuit layer CL includes a plurality of transistors Tr constituting the peripheral circuit PC (FIG. 1) and a plurality of wirings D0, D1, D2 and plurality of contacts CS connected to these plurality of transistors Tr. The transistor Tr is, for example, a field-effect transistor using the surface of the semiconductor substrate S as a channel region. In the surface of the semiconductor substrate S, regions that function as parts of the transistors Tr are surrounded by the insulating layers STI.

The memory layer ML includes a plurality of configurations included in the memory cell array MA. The memory layer ML includes a plurality of conductive layers 110 arranged in the Z-direction, semiconductor columns 120 extending in the Z-direction and facing to these plurality of conductive layers 110, gate insulating films 130 disposed between the plurality of conductive layers 110 and the semiconductor columns 120, and a conductive layer 140 connected to the lower ends of the semiconductor columns 120.

The conductive layer 110 is an approximately plate-shaped conductive layer extending in the X-direction. The conductive layers 110 are arranged in the Z-direction. The conductive layer 110 may include, for example, a stacked film or the like of titanium nitride (TiN) and tungsten (W) or may contain polycrystalline silicon or the like containing impurities of phosphorus, boron, or the like. Insulating layers 101 of silicon oxide (SiO₂) or the like are respectively disposed between two of the conductive layers 110.

Among the plurality of conductive layers 110, the one or plurality of conductive layers 110 positioned at the lowermost layer function as the source select line SGS (FIG. 1) and the gate electrodes of the plurality of source select transistors STS (FIG. 1) connected to this source select line SGS. Parts of the plurality of conductive layers 110 positioned above this function as the word lines WL (FIG. 1) and the gate electrodes of the plurality of memory cells MC (FIG. 1) connected to the word lines WL. The one or plurality of conductive layers 110 positioned further above this function as the drain select line SGD (FIG. 1) and the gate electrodes of the plurality of drain select transistors STD (FIG. 1) connected to this drain select line SGD.

The plurality of semiconductor columns 120 are arranged in the X-direction and the Y-direction. The semiconductor column 120 is, for example, a semiconductor layer including, for example, non-doped polycrystalline silicon (Si). The semiconductor column 120 has an approximately cylindrical shape and includes an insulating layer 121 at the center part. The insulating layer 121 includes silicon oxide or the like. Respective outer peripheral surfaces of the semiconductor columns 120 are surrounded by the conductive layers 110. The semiconductor column 120 has a lower end portion connected to the conductive layer 140. The semiconductor column 120 has an upper end portion connected to the bit line BL extending in the Y-direction via a contact Cb, a contact Ch and a semiconductor layer 124 containing N-type impurities of phosphorus (P) or the like. The respective semiconductor columns 120 function as channel regions of the plurality of memory cells MC and the select transistors (STD, STS) included in one memory string MS (FIG. 1).

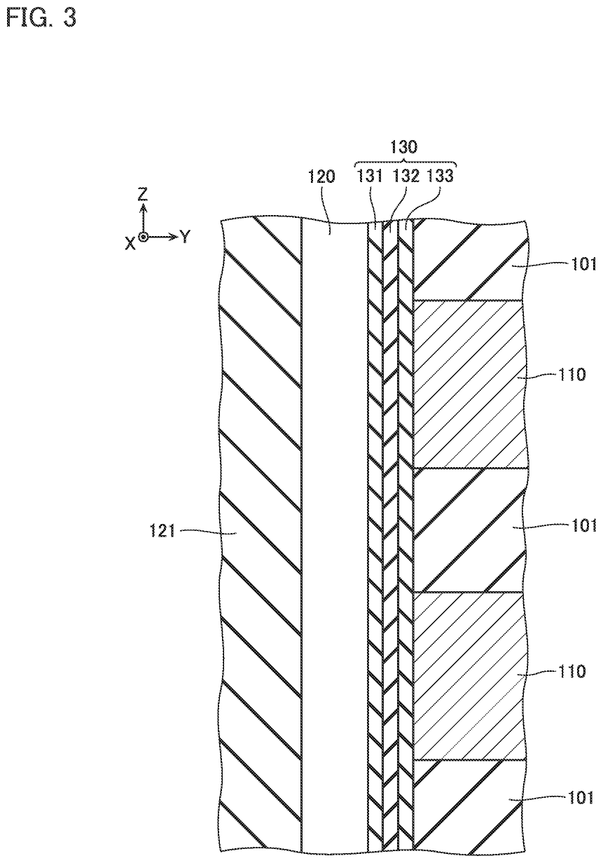

The gate insulating film 130 includes, for example, as illustrated in FIG. 3, a tunnel insulating film 131, an electric charge storage film 132, and a block insulating film 133, which are stacked between the semiconductor column 120 and the conductive layers 110. The tunnel insulating film 131 and the block insulating film 133 include, for example, insulating films of silicon oxide or the like. The electric charge storage film 132 includes a film that can storage an electric charge, such as silicon nitride (SiN) or the like. The tunnel insulating film 131, the electric charge storage film 132, and the block insulating film 133, which have approximately cylindrical shapes, extend in the Z-direction along the outer peripheral surface of the semiconductor column 120.

FIG. 3 illustrates an example in which the gate insulating film 130 includes the electric charge storage film 132 including silicon nitride or the like. However, the gate insulating film 130 may include, for example, a floating gate including polycrystalline silicon or the like containing N-type or P-type impurities.

For example, as illustrated in FIG. 2, the conductive layer 140 includes a conductive film 141 connected to the lower end portions of the semiconductor columns 120 and a conductive film 142 disposed on the lower surface of the conductive film 141. The conductive film 141 contains, for example, a semiconductor having a conductive property such as polysilicon containing N-type impurities, such as phosphorus (P). The conductive film 142 may contain, for example, a semiconductor having a conductive property such as polysilicon containing N-type impurities, such as phosphorus (P), may contain a metal, such as tungsten (W), or may contain silicide or the like.

Next, with reference to FIG. 4 to FIG. 11, the semiconductor memory device according to the embodiment will be described in more detail. Note that FIG. 4 to FIG. 11 illustrate schematic configurations, and the specific configurations are appropriately changeable. For convenience of description, FIG. 4 to FIG. 11 omit apart of configurations.

[Memory Layer ML]

FIG. 4 is a schematic plan view of the semiconductor memory device according to the embodiment. In the example of FIG. 4, the semiconductor substrate S includes the four memory cell arrays MA arranged in the X-direction and the Y-direction.

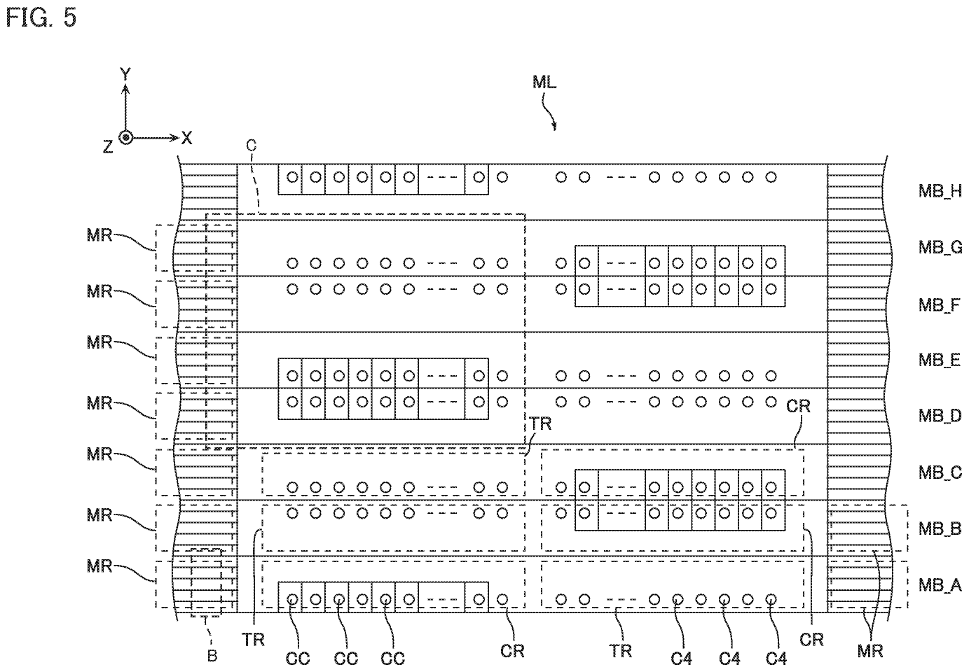

FIG. 5 is a schematic plan view illustrating a configuration in a region indicated by A in FIG. 4 and illustrates a configuration in the memory layer ML. As illustrated in FIG. 5, the memory cell arrays MA each include a plurality of memory blocks MB (MB_A to MB_H) arranged in the Y-direction. Additionally, the memory blocks MB each include two memory regions MR extending in the X-direction and arranged in the X-direction, a contact region CR disposed between these two memory regions MR, and a through contact region TR disposed between the contact region CR and the memory region MR.

In the example of FIG. 5, the contact region CR and the through contact regions TR are disposed in a staggered pattern. That is, in the memory blocks MB_A, MB_D, MB_E, MB_H, the through contact regions TR are disposed in the regions on one side in the X-direction (for example, the right side in FIG. 5), and the contact regions CR are disposed in the regions on the other side in the X-direction (for example, the left side in FIG. 5). Meanwhile, in the memory blocks MB_B, MB_C, MB_F, MB_G, the contact regions CR are disposed in the regions on one side in the X-direction (for example, the right side in FIG. 5), and the through contact regions TR are disposed in the regions on the other side in the X-direction (for example, the left side in FIG. 5). The contact region CR disposed in each memory block MB is adjacent to one contact region CR and one through contact region TR in the Y-direction. Similarly, the through contact region TR disposed in each memory block MB is adjacent to one contact region CR and one through contact region TR in the Y-direction.

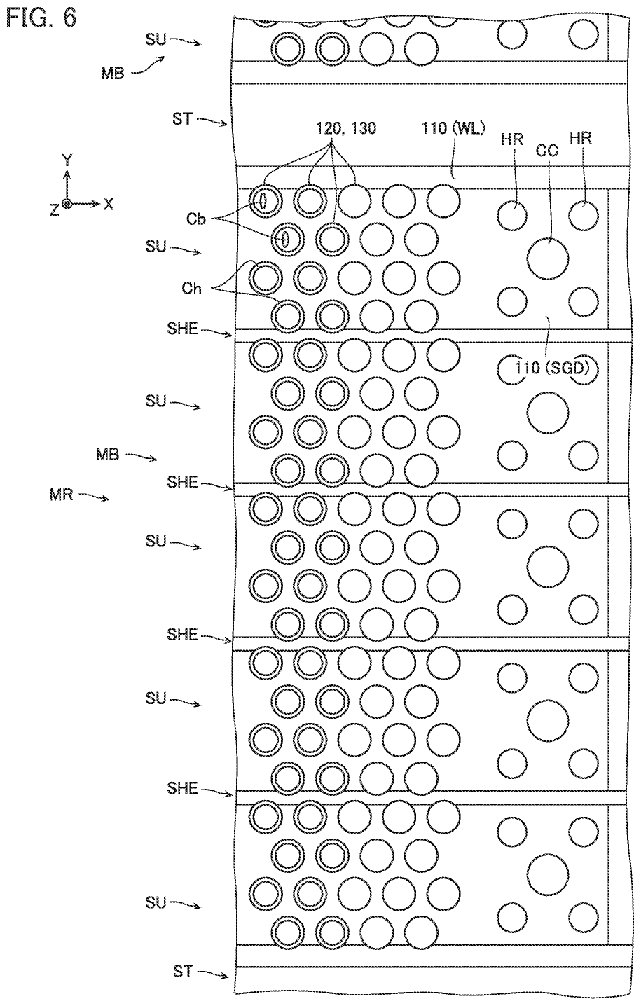

FIG. 6 is an enlarged view of a part of a region indicated by B in FIG. 5 and a schematic plan view illustrating the configuration in the memory region MR. In the example of FIG. 6, the memory region MR in each memory block MB includes the five string units SU arranged in the Y-direction. In each string unit SU, the plurality of semiconductor columns 120 and the gate insulating films 130 described above are disposed in the X-direction and the Y-direction. Further, between the two string units SU arranged in the Y-direction, an inter-string unit insulating layer SHE is disposed. The conductive layer 110 that functions as the drain select line SGD among the plurality of conductive layers 110 is separated in the Y-direction via the inter-string unit insulating layer SHE. These conductive layers 110 are each connected to the contact CC. At the proximity of the contact CC, insulating members HR having an approximately columnar shape that support the insulating layers 101 in a manufacturing process are disposed. Additionally, between two of the memory blocks MB arranged in the Y-direction, inter-memory block insulating layers ST are disposed respectively. Two of the plurality of conductive layers 110 are separated in the Y-direction via the inter-memory block insulating layers ST respectively.

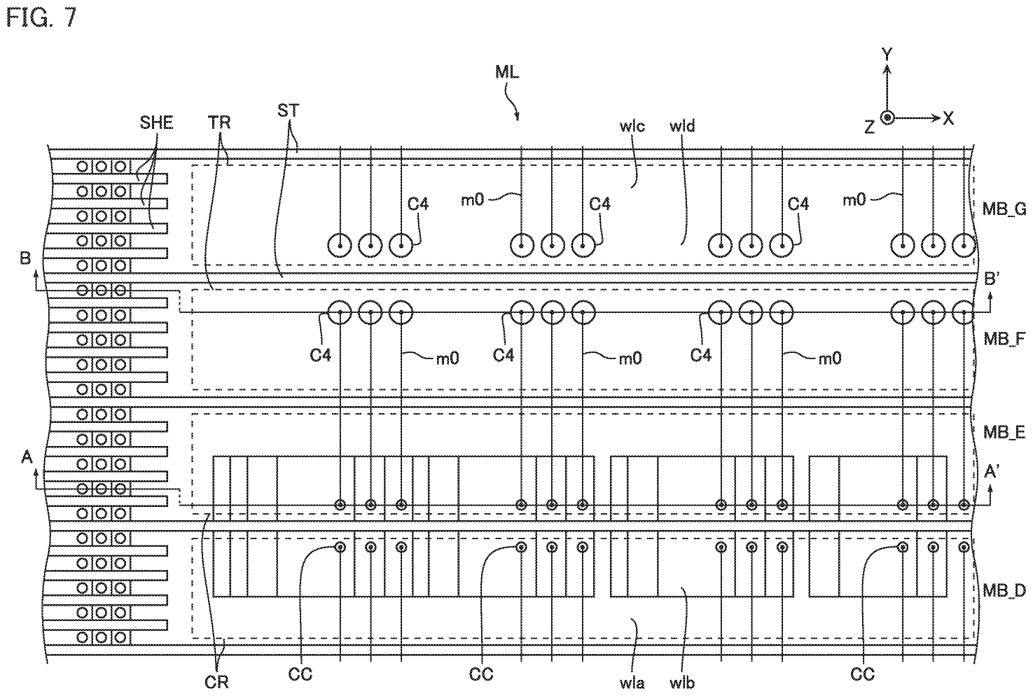

FIG. 7 is an enlarged view of a part of a region indicated by C in FIG. 5 and a schematic plan view illustrating configurations in the contact region CR and the through contact region TR.

The contact region CR includes a wiring region wla and a contact region wlb that extend in the X-direction and are arranged in the Y-direction. The wiring region wla includes parts of the plurality of conductive layers 110 arranged in the Z-direction. The parts of these conductive layers 110 extend in the X-direction along the inter-memory block insulating layer ST. Note that the contact CC is not disposed in the wiring region wla. The contact region wlb includes the plurality of contacts CC arranged in the X-direction and parts of the plurality of conductive layers 110 arranged in the Z-direction. The parts of these conductive layers 110 each include a connecting portion connected to one of the plurality of contacts CC and openings to connect the other contacts CC to the conductive layers 110 on the lower side.

The through contact region TR includes a wiring region wlc and a contact region wld that extend in the X-direction and are arranged in the Y-direction. The wiring region wlc includes parts of the plurality of conductive layers 110 arranged in the Z-direction. The parts of these conductive layers 110 extend in the X-direction along the inter-memory block insulating layer ST. Note that a through contact C4 is not disposed in the wiring region wlc. The contact region wld includes the plurality of through contacts C4 arranged in the X-direction and parts of the plurality of conductive layers 110 arranged in the Z-direction. The parts of these conductive layers 110 include a plurality of through-holes disposed corresponding to the through contacts C4.

As described with reference to FIG. 5, the memory blocks MB each include the memory region MR disposed on one side in the X-direction (for example, the right side in FIG. 5 and FIG. 7) and the memory region MR disposed on the other side in the X-direction (for example, the left side in FIG. 5 and FIG. 7). These two memory regions MR each include parts of the plurality of conductive layers 110 arranged in the Z-direction. The parts of these conductive layers 110 are connected to one another via the wiring region wla (FIG. 7) and the wiring region wlc (FIG. 7). These plurality of conductive layers 110 are connected to the plurality of transistors Tr disposed on the surface of the semiconductor substrate S via the plurality of contacts CC, wirings m0 extending in the Y-direction, and the through contacts C4.

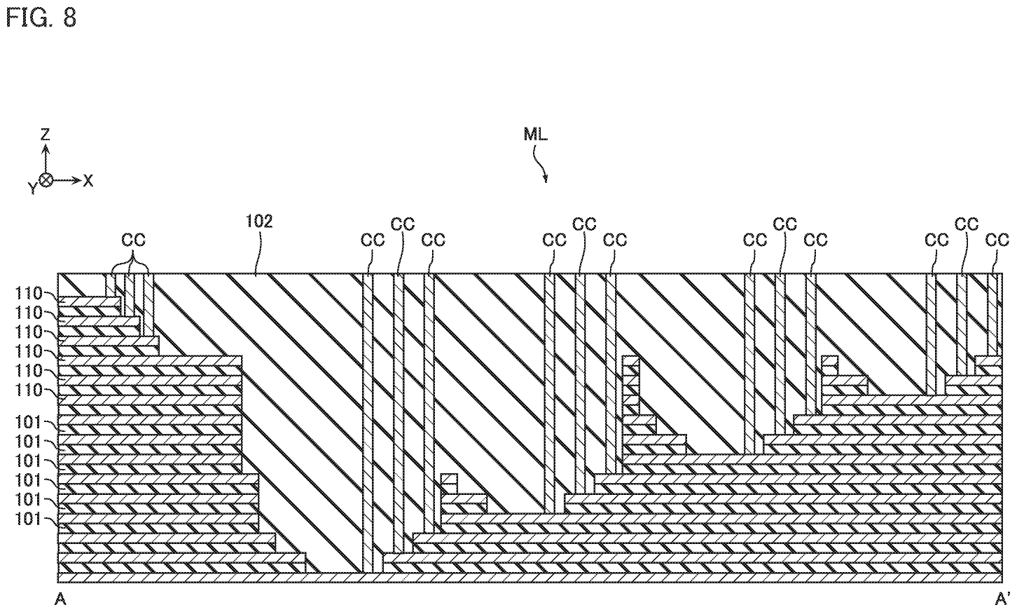

FIG. 8 is a schematic cross-sectional view of the configuration illustrated in FIG. 7 cut along the line A-A′ and viewed in the arrow direction. As illustrated in FIG. 8, the contacts CC extend in the Z-direction and are connected to the conductive layers 110 at the lower ends. Between two of the contacts CC, insulating layers 102, such as silicon oxide (SiO₂), are respectively disposed.

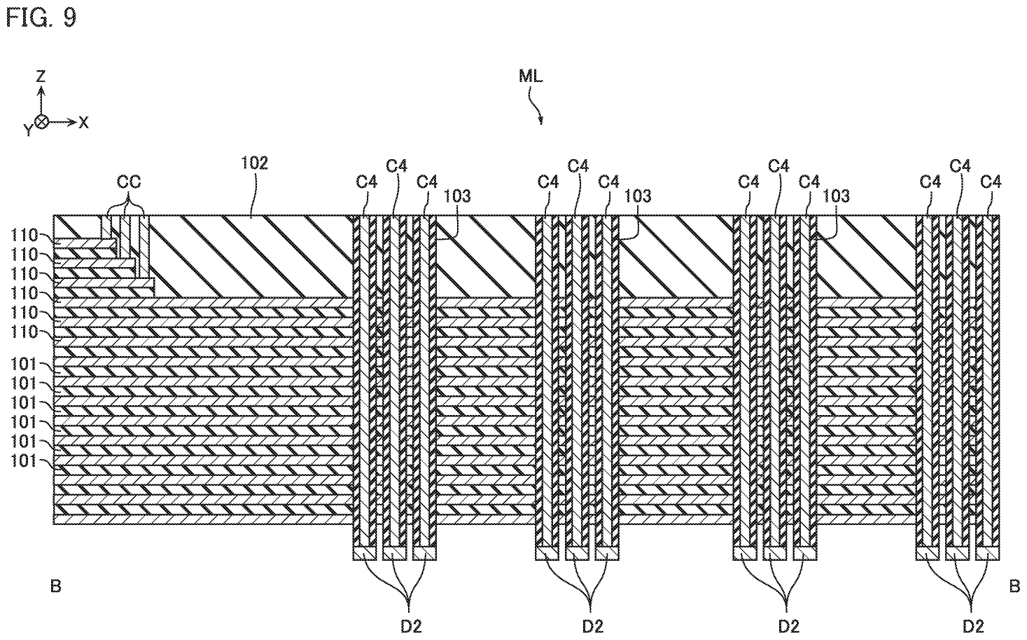

FIG. 9 is a schematic cross-sectional view of the configuration illustrated in FIG. 7 cut along the line B-B′ and viewed in the arrow direction. As illustrated in FIG. 9, the through contacts C4 extend in the Z-direction penetrating the plurality of conductive layers 110 and the plurality of insulating layers 101 and are connected to wirings D2 in the circuit layer CL. The respective through contacts C4 are electrically insulated from the conductive layers 110 via, for example, insulating layers. For example, in the illustrated example, insulating layers 103, such as silicon oxide (SiO₂), that cover the outer peripheral surfaces of the through contacts C4 are disposed between the respective through contacts C4 and the conductive layers 110, and the respective through contacts C4 are electrically insulated from the conductive layers 110 with the insulating layers 103. Note that the configuration is merely an example, and the specific configuration is appropriately adjustable. For example, a plurality of insulating layers, such as silicon nitride (SiN), arranged in the Z-direction may be disposed between the through contacts C4 and the conductive layers 110 via the plurality insulating layers 101, and the respective through contacts C4 may be electrically insulated from the conductive layers 110 with these plurality of insulating layers, such as silicon nitride. In this case, for example, the insulating layers 103 as illustrated in FIG. 9 as an example may be disposed or may be omitted.

[Circuit Layer CL]

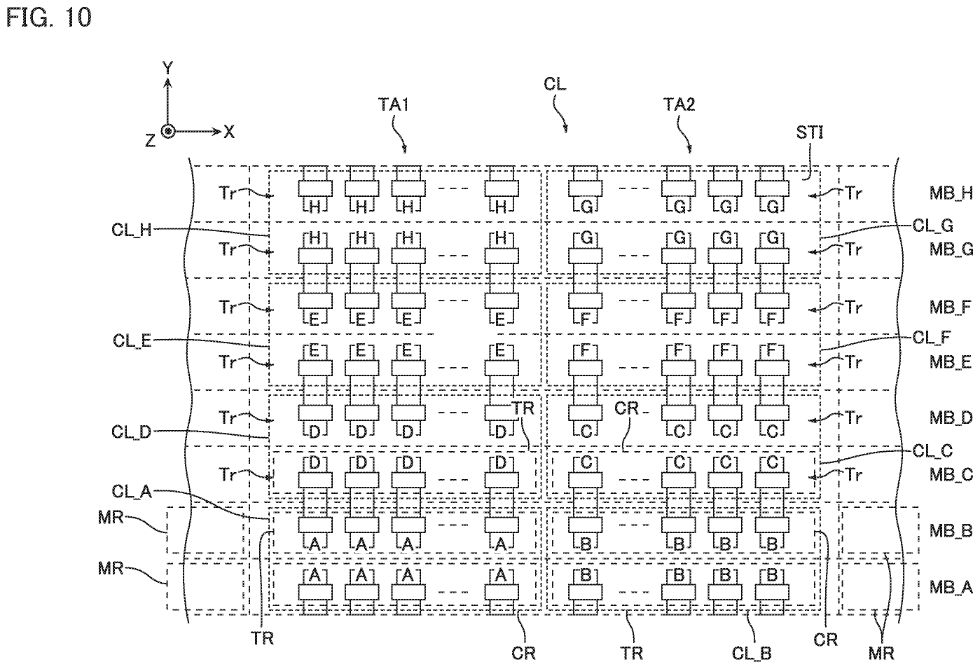

FIG. 10 is a schematic plan view illustrating arrangements of transistor arrays TA1 and TA2 disposed in the circuit layer CL positioned in a lower layer of the memory layer ML in FIG. 5. The transistor arrays TA1 and TA2 are arranged adjacently in the X-direction. The transistor arrays TA1 and TA2 include a plurality of transistors Tr for driving the memory blocks MB_A to MB_H. The circuit layer CL includes circuit regions CL_A to CL_H. These circuit regions CL_A to CL_H are disposed in respective vicinities of the contact regions CR and the through contact regions TR connected to the respective memory blocks MB_A to MB_H. The circuit regions CL_A to CL_H each include transistors Tr for driving each memory block MB_A to MB_H. Reference signs A to H attached to respective transistors Tr correspond to the last reference signs of the memory blocks MB_A to MB_H driven by the transistors Tr. For example, in a region where the transistor array TA1 illustrated on the left side of the drawing is disposed, the circuit regions CL_A, CL_D, CL_E, and CL_H for driving the respective memory blocks MB_A, MB_D, MB_E, and MB_H are disposed in every two memory blocks MB arranged in the Y-direction. Furthermore, in a region where the transistor array TA2 illustrated on the right side of the drawing is disposed, the circuit regions CL_B, CL_C, CL_F, and CL_G for driving the respective memory blocks MB_B, MB_C, MB_F, and MB_G are disposed in every two memory blocks MB arranged in the Y-direction. The arrangement of the circuit regions CL_A to CL_H is merely an example and other arrangements may be used.

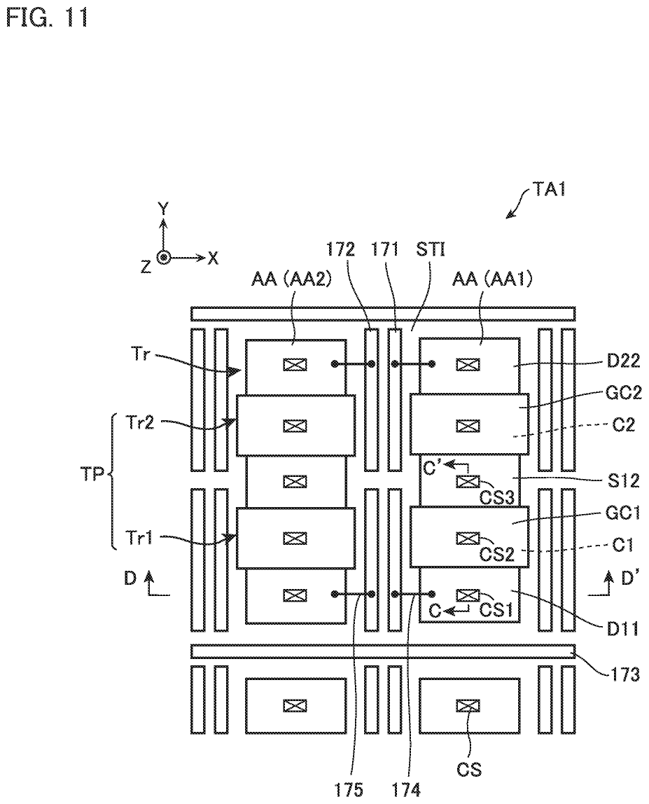

FIG. 11 is an enlarged plan view of a part of the transistor array TA1 in FIG. 10. Since the transistor array TA2 has a similar configuration to the transistor array TA1, its description is omitted. The transistor array TA1 includes a plurality of transistors Tr arranged in a matrix in the X-direction and the Y-direction. These plurality of transistors Tr each function as the block driving transistor 35 (FIG. 1). In the illustrated example, an arrangement period in the Y-direction of the transistor Tr corresponds to an arrangement period in the Y-direction of the memory block MB.

The plurality of transistors Tr include transistor pairs TP. One transistor pair TP includes one pair made of a first transistor Tr1 and a second transistor Tr2 adjacent in the Y-direction. The transistor pairs TP are arranged in the X-direction and the Y-direction. The transistor pair TP is formed in an active region AA of the semiconductor substrate S. Each active region AA includes, for example, a drain region D11 (first region), a channel region C1 (second region), a source region S12 (third region), a channel region C2 (fourth region), and a drain region D22 (fifth region) sequentially in the Y-direction. Gate electrodes GC1 and GC2 are respectively disposed above the channel regions C1 and C2. The drain region D11 and the gate electrode GC1 function as a drain and a gate of the first transistor Tr1, respectively. The gate electrode GC2 and the drain region D22 function as a gate and a drain of the second transistor Tr2, respectively. The source region S12 functions as a common source of the first transistor Tr1 and the second transistor Tr2. The first transistor Tr1 and the second transistor Tr2 adjacent to one another of the two transistor pairs TP adjacent in the Y-direction function as the block driving transistor 35(FIG. 1) that drives a same memory block MB.

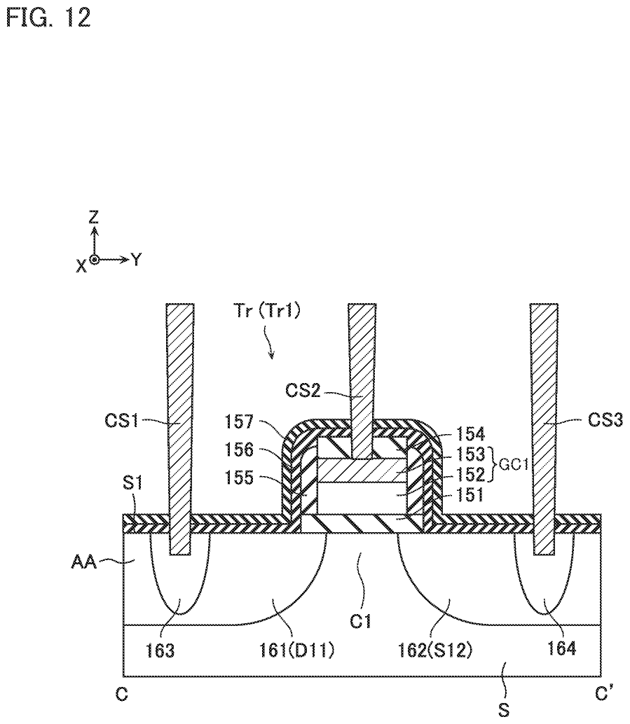

FIG. 12 is a schematic cross-sectional view of one transistor Tr (first transistor Tr1) illustrated in FIG. 11 cut along the line C-C′ and viewed in the arrow direction. The transistor Tr is, for example, an N type transistor that exhibits high breakdown voltage. The transistor Tr includes, for example, the active region AA close to the main surface S1 of the semiconductor substrate S including single-crystal silicon (Si) or the like, a gate insulating layer 151 including silicon oxide (SiO₂) or the like disposed on an upper surface of the active region AA, and the gate electrode GC1. The gate electrode GC1 includes a gate electrode member 152 including polycrystalline silicon (Si) or the like disposed on an upper surface of the gate insulating layer 151, and a gate electrode member 153 including tungsten (W) or the like disposed on an upper surface of the gate electrode member 152. A cap insulating layer 154 including silicon oxide (SiO₂), silicon nitride (Si₃N₄), or the like is disposed on an upper surface of the gate electrode member 153. A sidewall insulating layer 155 including silicon oxide (SiO₂), silicon nitride (Si₃N₄), or the like is disposed on side surfaces in the X-direction or the Y-direction of the gate electrode member 152, the gate electrode member 153, and the cap insulating layer 154. The gate electrode member 152 may contain, for example, N-type impurities, such as phosphorus (P) or arsenic (As), or P-type impurities, such as boron (B).

Furthermore, the transistor Tr includes liner insulating layers 156 and 157 stacked on the main surface S1 of the semiconductor substrate S, side surfaces in the X-direction or the Y-direction of the gate insulating layer 151, side surfaces in the X-direction or the Y-direction of the sidewall insulating layer 155, and an upper surface of the cap insulating layer 154. The liner insulating layer 156 includes silicon oxide (SiO₂) or the like, and the liner insulating layer 157 includes silicon nitride (Si₃N₄) or the like.

A channel region C1 is disposed in the active region AA of the semiconductor substrate S immediately below the gate insulating layer 151. A low concentration impurity layer 161 that functions as the drain region D11 is disposed on one side in the Y-direction with respect to the channel region C1 of the active region AA, and a low concentration impurity layer 162 that functions as the source region S12 is disposed on the other side. High concentration impurity layers 163 and 164 are further disposed inside the low concentration impurity layers 161 and 162, respectively. The low concentration impurity layers 161 and 162, and the high concentration impurity layers 163 and 164 contain, for example, N-type impurities, such as phosphorus (P) or arsenic (As). Furthermore, impurity concentrations of the N-type impurities in the high concentration impurity layers 163 and 164 are greater than impurity concentrations of the N-type impurities in the low concentration impurity layers 161 and 162, respectively.

Furthermore, three contacts CS1, CS2, and CS3 extending in the Z-direction are connected to the transistor Tr. The contacts CS1 to CS3 may include, for example, a stacked film of a barrier conductive film, such as titanium nitride (TiN), and a metallic film, such as tungsten (W). The contact CS1 constitutes a part of a drain electrode, penetrates the liner insulating layers 156 and 157, and is connected to the high concentration impurity layer 163 of the drain region D11. The contact CS2 constitutes a part of the gate electrode, penetrates the liner insulating layers 156, 157, and the cap insulating layer 154, and is connected to the upper surface of the gate electrode member 153. The contact CS3 constitutes a part of a source electrode, penetrates the liner insulating layers 156 and 157, and is connected to the high concentration impurity layer 164 of the source region S12. The contact CS1 is connected, for example, to the word line WL illustrated in FIG. 1. The contact CS2 is connected, for example, to the block select line BLKSEL illustrated in FIG. 1. The contact CS3 is connected, for example, to the wiring CG illustrated in FIG. 1.

The second transistor Tr2 has a left-right inverted configuration of a configuration in FIG. 12.

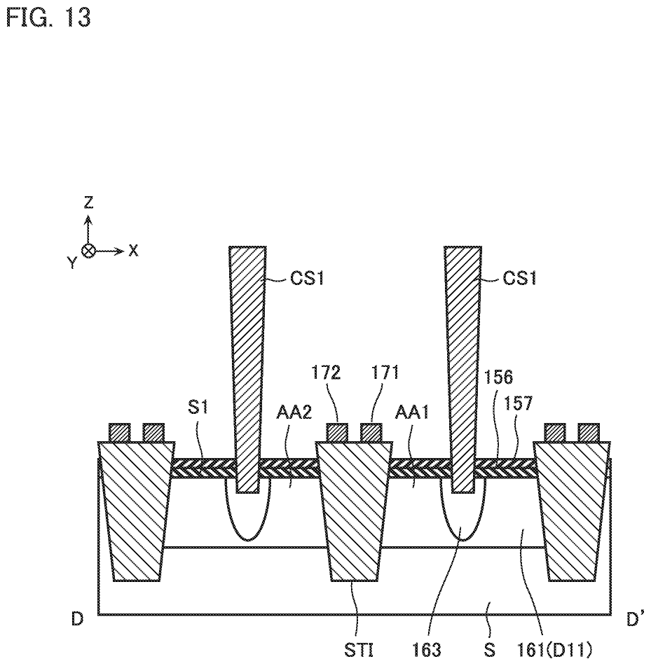

FIG. 13 is a schematic cross-sectional view of two transistor pairs TP adjacent in the X-direction illustrated in FIG. 11 cut along the line D-D′ and viewed in the arrow direction. Here, among the active regions AA adjacent in the X-direction of the semiconductor substrate S, one (on the right side of the drawing) is referred to as a first active region AA1, and the other (on the left side of the drawing) as a second active region AA2. The first active region AA1 and the second active region AA2 are separated in the X-direction by the insulating layer STI. An upper surface of the insulating layer STI is positioned between the upper surface and lower surface of the gate electrode member 152 (FIG. 12), and a lower surface of the insulating layer STI extends below the low concentration impurity layer 161.

A first electrode 171 and a second electrode 172 are disposed on the upper surface of the insulating layer STI. The first electrode 171 and the second electrode 172 are arranged in the X-direction such that the first electrode 171 is on a first active region AA1 side while the second electrode 172 is on the second active region AA2 side. As illustrated in FIG. 11, the first electrode 171 and the second electrode 172 extend in the Y-direction, are respectively arranged in sidewards of the first transistor Tr1 and the second transistor Tr2, and are separated between the first transistor Tr1 and the second transistor Tr2. Furthermore, as illustrated in FIG. 11, a third electrode 173 extending in the X-direction is disposed on the upper surface of the insulating layer STI arranged between the two transistor pairs TP adjacent in the Y-direction. The first electrode 171, the second electrode 172, and the third electrode 173 contain, for example, polycrystalline silicon (Si), or the like. The first electrode 171, the second electrode 172, and the third electrode 173 may contain, for example, N-type impurities, such as phosphorus (P) or arsenic (As), or P-type impurities, such as boron (B).

As illustrated in FIG. 11, the first electrode 171 is connected to the drain of the first active region AA1 via a wiring 174, and the second electrode 172 is connected to the drain of the second active region AA2 via a wiring 175. The third electrode 173 is electrically connected to a ground voltage supply terminal.

[Write Operation]

Next, a write operation of data into the selected memory block MB of the semiconductor memory device configured as above is described.

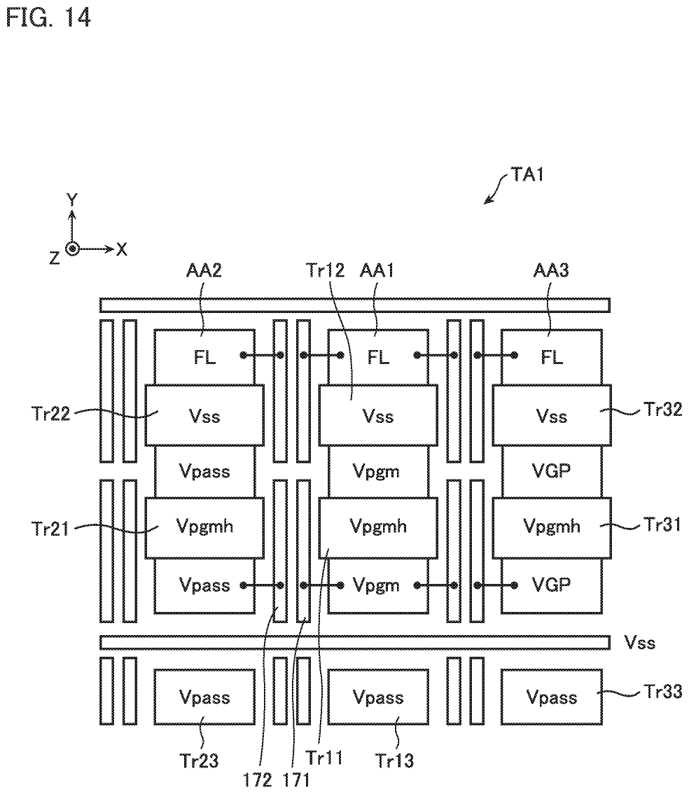

FIG. 14 is a schematic plan view illustrating a voltage applied state for each transistor Tr in the write operation. Transistors Tr11 and Tr12 are disposed in the first active region AA1 at the center. Transistors Tr21 and Tr22 are disposed on one side (on the left side of the drawing) in the X-direction with respect to the first active region AA1. Transistors Tr31 and Tr32 are disposed on the other side (on the right side of the drawing) in the X-direction with respect to the first active region AA1. Furthermore, transistors adjacent to the respective transistors Tr11, Tr21, and Tr31 in the Y-direction and disposed in different active regions AA are assumed to be transistors Tr13, Tr23, and Tr33.

Assume that the memory blocks MB driven by the transistors Tr11, Tr21, Tr31, Tr13, Tr23, and Tr33 are in a selected state, and the memory blocks MB driven by the other transistors Tr12, Tr22, and Tr32 are in an unselected state. In this case, a voltage Vpgmh is applied to the gates of the transistors Tr11, Tr21, Tr31, Tr13, Tr23, and Tr33 in the selected blocks. Furthermore, a voltage Vss is applied to the gates of the transistors Tr12, Tr22, and Tr32 in the unselected blocks. As a result, the transistors Tr11, Tr21, Tr31, Tr13, Tr23, and Tr33 are turned ON, and the transistors Tr12, Tr22, and Tr32 are turned OFF.

In the above state, when applying the write voltage Vpgm to the word line WL connected to the drain of the transistor Tr11, a voltage Vpgm is applied to the source of the transistor Tr11. Furthermore, a voltage Vpass and a voltage VGP are respectively applied to the sources of transistors Tr21 and Tr31 adjacent in the X-direction to the transistor Tr11. As a result, the voltages Vpgm, Vpass, and VGP are respectively output to the drains of the ON state transistors Tr11, Tr21, and Tr31. The voltage Vpass is output to the drains of the transistors Tr31, Tr32, and Tr33 adjacent in the Y-direction of the transistors Tr11, Tr21, and Tr31 . On the other hand, the drains of the transistors Tr12, Tr22, and Tr32 in the unselected blocks enter a floating state (FL).

Here, a magnitude relation of respective voltages is voltage Vpgmh>voltage Vpgm>voltage Vpass>voltage VGP>voltage Vss. The first electrode 171 and the second electrode 172 have voltages equivalent to a drain voltage of the adjacent transistor Tr. Therefore, a higher voltage Vpgm is applied to the first electrode 171 and the second electrode 172 on both sides in the X-direction of the transistor Tr11 to which the higher voltage Vpgm is transferred. On the other hand, lower voltages Vpass, VGP, and Vss are applied to the first electrodes 171 and the second electrodes 172 on both sides in the X-direction of the other transistors Tr21, Tr31, Tr12, Tr22, Tr32, Tr13, Tr23, and Tr33.

[Effect of First Embodiment]

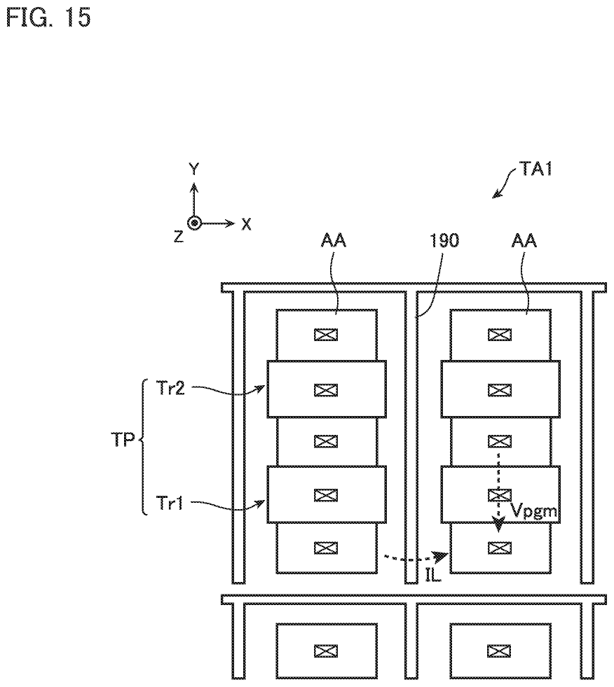

FIG. 15 is an enlarged plan view of a part of a transistor array TA1 according to a comparative example. In the transistor array according to the comparative example, one shield electrode 190 is formed so as to surround each transistor pair TP along the insulating layer STI surrounding the transistor pair TP. The voltage Vss is applied to the shield electrode 190. Accordingly, generation of a leakage current IL between adjacent transistors Tr via the insulating layer STI is reduced.

However, in the case of the comparative example, since the voltage Vss that is lower than the voltage Vpgm is applied to the shield electrode 190, a transferring capacity of the voltage Vpgm of the transistor Tr that performs the writing decreases. Due to the integration of the transistor along with the highly stacked and highly integrated semiconductor memory devices, the trend becomes remarkable. This makes it difficult to make a transistor Tr to transistor Tr pitch decrease, and increases an occupying proportion of a chip area in the transistor array TA. The trend is particularly remarkable in a transistor that exhibits high breakdown voltage, such as a memory block select transistor in a semiconductor memory device.

Meanwhile, in the semiconductor memory device according to the embodiment, since the first electrode 171 and the second electrode 172 on both sides of the transistor Tr11 performing the writing have voltages equivalent to the higher voltage Vpgm that is transferred, the transferring capacity of the transistor Tr11 performing the writing is improved.

On the other hand, since the first electrodes 171 and the second electrodes 172 on both sides of the transistors Tr other than the transistor Tr11 performing the writing can have lower voltages, the reduction effect of the leakage current between the transistors Tr can be maintained. Therefore, the pitch of the transistor Tr is ensured to be decreased, thus ensuring the decreased chip size.

Furthermore, in the first embodiment, since the first electrodes 171 and the second electrodes 172 are configured to be connected to the drains of the transistors Tr adjacent in the X-direction, thus ensuring simple wiring.

### Second Embodiment

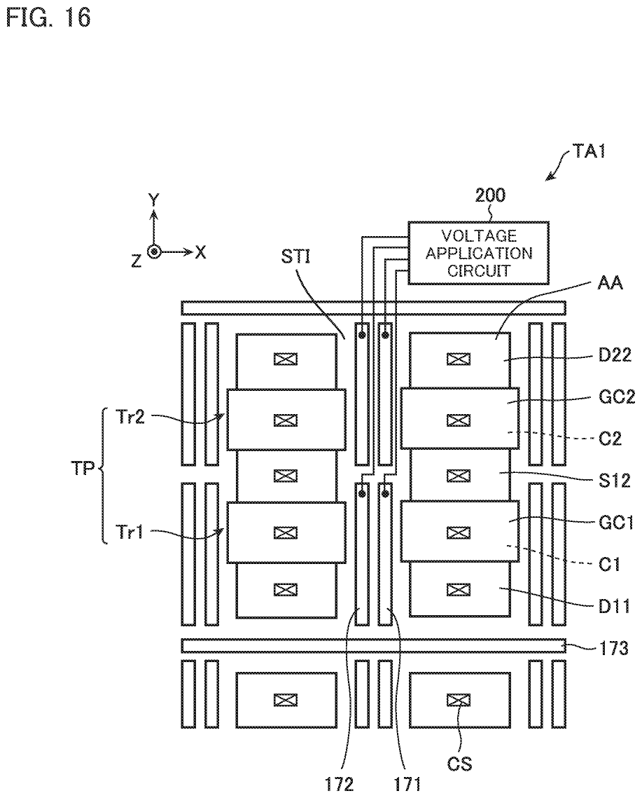

FIG. 16 is an enlarged plan view of a part of the transistor array TA1 according to the second embodiment. In the second embodiment, parts that are the same as the first embodiment are attached the same reference numerals, and descriptions of overlapping parts are omitted.

In the second embodiment, as illustrated in FIG. 16, the first electrode 171 and the second electrode 172 are connected to a voltage application circuit 200. The voltage application circuit 200 may use a part of the operating voltage generation circuit 21 illustrated in FIG. 1, or use another circuit. The voltage application circuit 200, for example, applies the higher voltage Vpgm to the first electrode 171 and the second electrode 172 on both sides of the transistor Tr performing the writing, and, for example, applies the voltage Vss to the first electrode 171 and the second electrode 172 on both sides of another transistor Tr.

According to the second embodiment, the first electrode 171 and the second electrode 172 can be driven independently. Therefore, for example, the most effective voltage can be applied based on two aspects, “reduction of leakage current between the adjacent transistors Tr” and “maintenance of voltage transferring capacity in the transistor Tr performing writing”.

### Third Embodiment

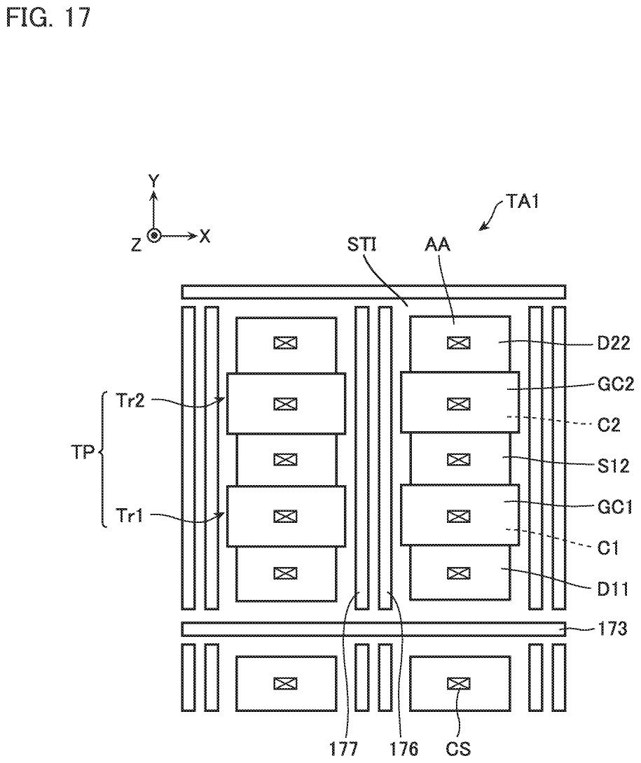

FIG. 17 is an enlarged plan view of a part of the transistor array TA1 according to the third embodiment. In the third embodiment, parts that are the same as the first embodiment are attached the same reference numerals, and descriptions of overlapping parts are omitted.

In the third embodiment, as illustrated in FIG. 17, a first electrode 176 and a second electrode 177 are formed continuously in the Y-direction without separation for the first transistor Tr1 and the second transistor Tr2 inside the transistor pair TP.

According to the third embodiment, the first electrode 176 and the second electrode 177 cannot be controlled independently corresponding to the first transistor Tr1 and the second transistor Tr2. However, applying the voltage Vpgm that supports the transfer of the write voltage Vpgm or a lower voltage to the first electrode 176 and applying the voltage Vss that reduces the leakage current of the adjacent transistor Tr or a higher voltage to the second electrode 177 can provide an effect similar to the first embodiment. Furthermore, the third embodiment can reduce the overall number of the first electrodes 176 and the second electrodes 177, thus allowing the simplified wiring.

### Fourth Embodiment

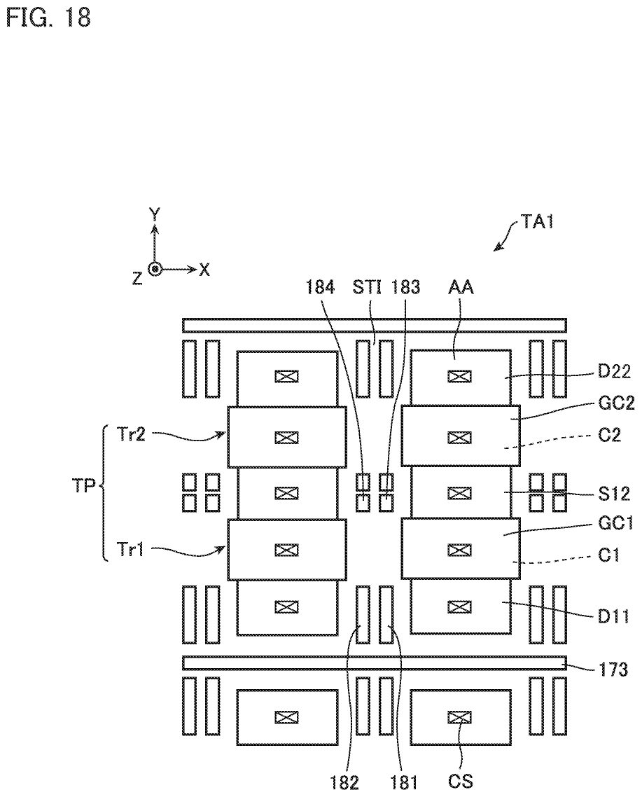

FIG. 18 is an enlarged plan view of a part of the transistor array TA1 according to the fourth embodiment. In the fourth embodiment, parts that are the same as the first embodiment are attached the same reference numerals, and descriptions of overlapping parts are omitted.

In the fourth embodiment, as illustrated in FIG. 18, a first electrode 181 and a second electrode 182 are disposed between the drain regions D11 and D11 and between the drain regions D22 and D22 of two transistors Tr adjacent in the X-direction, and a first electrode 183 and a second electrode 184 are disposed between the source regions S12 and S12 of two transistors Tr adjacent in the X-direction. The first electrode 183 and the second electrode 184 are separated in the Y-direction respectively corresponding to the first transistor Tr1 and the second transistor Tr2.

In the fourth embodiment, since the first electrode 181 or 183 or the second electrode 182 or 184 does not exist between the gate electrodes GC1 and GC1 of the first transistors Tr1 or between the gate electrodes GC2 and GC2 of the second transistors Tr2 adjacent in the X-direction, it is possible to avoid the gate electrodes GC1 and GC2 from approaching and contacting the first electrode 181 or 183 or the second electrode 182 or 184. Therefore, the array pitch in the X-direction of the transistor Tr can be further decreased.

### Fifth Embodiment

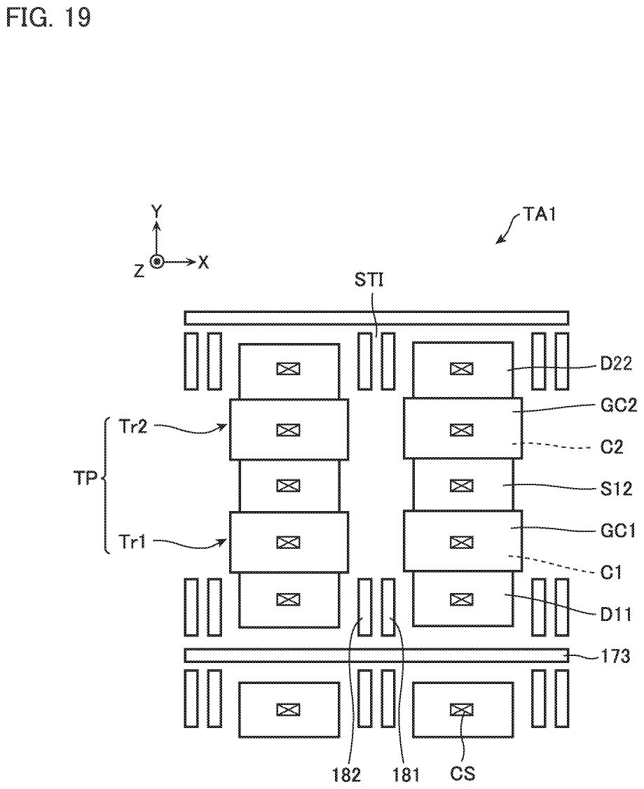

FIG. 19 is an enlarged plan view of a part of the transistor array TA1 according to the fifth embodiment. In the fifth embodiment, parts that are the same as the fourth embodiment are attached the same reference numerals, and descriptions of overlapping parts are omitted.

In the fifth embodiment, as illustrated in FIG. 19, the first electrode 183 and the second electrode 184 in the fourth embodiment are omitted. The leakage between the adjacent transistors Tr and the transfer of the write voltage Vpgm have the largest influence in the drain regions D11 and D22. Therefore, even in the fifth embodiment, an effect similar to the fourth embodiment can be obtained. Furthermore, in the embodiment, the wiring is easier than the fourth embodiment.

[Others]

While the first to fifth embodiments have been described, these embodiments have been presented by way of example only, and are not intended to limit the scope of the inventions. Indeed, the novel embodiments described herein may be embodied in a variety of other forms: furthermore, various omissions, substitutions and changes in the form of the methods and systems described herein may be made without departing from the spirit of the inventions. For example, in each of the above-described embodiment, two transistors Tr are formed in one active region AA but, for example, four transistors Tr may be formed in one cross shaped semiconductor layer. Furthermore, in each of the above-described embodiment, an N channel type transistor that exhibits high breakdown voltage. The N channel type transistor drives the semiconductor memory device is raised as an example, but each of the above-described embodiment is applicable to a P channel type transistor that exhibits high breakdown voltage by a polarity inversion. Furthermore, each of the above-described embodiment is also applicable to a P type or N type transistor that exhibits low breakdown voltage. Furthermore, each of the above-described embodiment is applicable to semiconductor devices other than the semiconductor memory device. The accompanying claims and their equivalents are intended to cover such forms or modifications as would fall within the scope and spirit of the inventions.

What is claimed is:

1. A semiconductor device comprising:
a semiconductor substrate;
an element isolation provided on the semiconductor substrate; and
a plurality of conductive layers facing to the semiconductor substrate and the element isolation, wherein the semiconductor substrate includes a first active region and a second active region arranged in a first direction along a main surface of the semiconductor substrate,
the element isolation is provided between the first active region and the second active region,
the semiconductor device includes a first gate insulating film and a second gate insulating film respectively facing to the first active region and the second active region, in a second direction intersecting with the main surface of the semiconductor substrate, and
the plurality of conductive layers include:
a first gate electrode and a second gate electrode respectively facing to the first gate insulating film and the second gate insulating film, in the second direction; and
a first electrode and a second electrode facing to the element isolation in the second direction and arranged in the first direction, the first electrode being disposed on the first active region side, the second electrode being disposed on the second active region side.

2. The semiconductor device according to claim 1, wherein
the first active region and the second active region each include a first region, a second region, and a third region sequentially arranged in a third direction intersecting with the first direction and the second direction, and
the first electrode and the second electrode are disposed at least between the first region of the first active region and the first region of the second active region, viewed from the second direction.

3. The semiconductor device according to claim 1, wherein
the semiconductor device is configured to be able to simultaneously apply different voltages to the first electrode and the second electrode.

4. The semiconductor device according to claim 2, wherein
the semiconductor device is configured to be able to apply a voltage higher than a voltage applied to the second electrode, to the first electrode when a voltage of the first region of the first active region is higher than a voltage of the first region of the second active region.

5. The semiconductor device according to claim 2, wherein
the first region of the first active region and the first electrode are electrically connected, and
the first region of the second active region and the second electrode are electrically connected.

6. The semiconductor device according to claim 2, further comprising
a third active region disposed on a side opposite to the second active region in the first direction, with respect to the first active region, wherein
the element isolation including a first element isolation insulating and a second element isolation insulating, the second element isolation insulating is disposed between the first active region and the third active region, and
the plurality of conductive layers include a third electrode and a fourth electrode facing to the second element isolation insulating in the second direction and arranged in the first direction, the third electrode being disposed on the first active region side, the fourth electrode being disposed on the third active region side.

7. The semiconductor device according to claim 6, wherein
the third active region includes a fourth region, a fifth region, and a sixth region sequentially arranged in the third direction, and
the third electrode and the fourth electrode are disposed at least between the first region and the fourth region, viewed from the second direction.

8. The semiconductor device according to claim 6, wherein
the semiconductor device is configured to be able to simultaneously apply different voltages to the third electrode and the fourth electrode.

9. The semiconductor device according to claim 7, wherein
the semiconductor device is configured to be able to apply a voltage higher than a voltage applied to the fourth electrode, to the third electrode when a voltage of the first region is higher than a voltage of the fourth region.

10. A semiconductor device comprising:
a semiconductor substrate;
a first transistor disposed on the semiconductor substrate;
a second transistor disposed on the semiconductor substrate and arranged on one side in the first direction along a main surface of the semiconductor substrate with respect to the first transistor;
a third transistor disposed on the semiconductor substrate and arranged on the other side in the first direction with respect to the first transistor;
a first element isolation disposed between the first transistor and the second transistor;
a second element isolation disposed between the first transistor and the third transistor;
a first electrode facing to the first element isolation, in a second direction intersecting with the main surface of the semiconductor substrate, between a drain of the first transistor and a drain of the second transistor;
a second electrode facing to the first element isolation in the second direction, between the first electrode and the drain of the second transistor;
a third electrode facing to the second element isolation in the second direction, between the drain of the first transistor and a drain of the third transistor; and
a fourth electrode facing to the second element isolation in the second direction, between the third electrode and the drain of the third transistor.

11. The semiconductor device according to claim 10, wherein
the semiconductor device is configured to be able to apply a voltage higher than a voltage applied to the second electrode and a voltage applied to the fourth electrode, to the first electrode and the third electrode when a drain voltage of the first transistor is higher than a drain voltage of the second transistor and a drain voltage of the third transistor.

12. The semiconductor device according to claim 11, wherein
the drain of the first transistor, the first electrode, and the third electrode are electrically connected,
the drain of the second transistor and the second electrode are electrically connected, and
the drain of the third transistor and the fourth electrode are electrically connected.

13. The semiconductor device according to claim 10, comprising:
a fourth transistor disposed on the semiconductor substrate and arranged with the first transistor in a third direction intersecting with the first direction and the second direction, the fourth transistor having a source shared with the first transistor;
a fifth transistor disposed on the semiconductor device and arranged with the second transistor in the third direction, the fifth transistor having a source shared with the second transistor; and
a sixth transistor disposed on the semiconductor device and arranged with the third transistor in the third direction, the sixth transistor having a source shared with the third transistor.

14. The semiconductor device according to claim 13, comprising:
a fifth electrode facing to the first element isolation in the second direction, between a drain of the fourth transistor and a drain of the fifth transistor;
a sixth electrode facing to the first element isolation in the second direction, between the fifth electrode and the drain of the fifth transistor;
a seventh electrode facing to the second element isolation in the second direction, between the drain of the fourth transistor and a drain of the sixth transistor; and
an eighth electrode facing to the second element isolation in the second direction, between the seventh electrode and the drain of the sixth transistor.

15. The semiconductor device according to claim 14, wherein
the first electrode and the fifth electrode, the second electrode and the sixth electrode, the third electrode and the seventh electrode, the fourth electrode and the eighth electrode are each arranged in the second direction, and each electrically insulated from one another.

16. A semiconductor memory device comprising:
a semiconductor substrate;
an element isolation disposed on the semiconductor substrate;
a plurality of conductive layers facing to the semiconductor substrate and the element isolation; and
a memory cell array electrically connected to the semiconductor substrate, wherein
the semiconductor substrate includes a first active region and a second active region arranged in a first direction along a main surface of the semiconductor substrate,
the element isolation is disposed between the first active region and the second active region,
the semiconductor memory device includes a first gate insulating film and a second gate insulating film respectively facing to the first active region and the second active region, in a second direction intersecting with the main surface of the semiconductor substrate,
the plurality of conductive layers include:
a first gate electrode and a second gate electrode respectively facing to the first gate insulating film and the second gate insulating film, in the second direction; and
a first electrode and a second electrode facing to the element isolation in the second direction and arranged in the first direction, the first electrode being disposed on the first active region side, the second electrode being disposed on the second active region side, and
the memory cell array is electrically connected to the first active region and the second active region of the semiconductor substrate.

17. The semiconductor memory device according to claim 16, wherein
the first active region and the second active region each include a first region, a second region, and a third region sequentially arranged in a third direction intersecting with the first direction and the second direction, and
the first electrode and the second electrode are disposed at least between the first region of the first active region and the first region of the second active region, viewed from the second direction.

18. The semiconductor memory device according to claim 16, wherein
the semiconductor device is configured to be able to simultaneously apply different voltages to the first electrode and the second electrode.

19. The semiconductor memory device according to claim 17, wherein
the semiconductor device is configured to be able to apply a voltage higher than a voltage applied to the second electrode, to the first electrode when a voltage of the first region of the first active region is higher than a voltage of the first region of the second active region.

20. The semiconductor memory device according to claim 17, wherein
the first region of the first active region and the first electrode are electrically connected, and
the first region of the second active region and the second electrode are electrically connected.
